(19) United States
(12) Patent Application Publication
(10) Pub. No.: US 2024/0014031 A1
(43) Pub. Date: Jan. 11, 2024

(54) FILM DEPOSITION METHOD AND FILM DEPOSITION APPARATUS

(71) Applicant: Tokyo Electron Limited, Tokyo (JP)

(72) Inventors: Shota CHIDA, Yamanashi (JP); Yosuke WATANABE, Yamanashi (JP); Keisuke SUZUKI, Yamanashi (JP)

(21) Appl. No.: 18/345,134

(22) Filed: Jun. 30, 2023

(30) Foreign Application Priority Data
Jul. 8, 2022 (JP) 2022-110733

(51) Int. Cl. H01L 21/02; C23C 16/34; C23C 16/52

(52) U.S. Cl. CPC H01L 21/0217; H01L 21/0228; C23C 16/345; C23C 16/52

(57) ABSTRACT

With respect to a film deposition method of depositing a silicon nitride film doped with a desired metal on a substrate, the film deposition method includes (a) supplying a silicon-containing gas into a processing chamber in which the substrate is accommodated, (b) supplying a metal-containing gas into the processing chamber, the metal-containing gas containing the desired metal, (c) supplying a nitrogen-containing gas into the processing chamber, after performing (a) at least once and performing (b) at least once.

### CROSS-REFERENCE TO RELATED APPLICATIONS

This patent application is based on and claims priority to Japanese Patent Application No. 2022-110733 filed on Jul. 8, 2022, the entire contents of which are incorporated herein by reference.

### TECHNICAL FIELD

The present disclosure relates to a film deposition method and a film deposition apparatus.

### BACKGROUND

In a 3D NAND memory, a semiconductor in which silicon nitride films (SiN films) are stacked is used to trap high-density charges, for example. In the SiN film, the charge write/erase characteristic and the charge retention characteristic are in a trade-off relationship. In order to improve these characteristics, a SiN film doped with a desired metal such as aluminum (Al) is developed in recent years.

For example, Patent Document 1 discloses a method of forming a metal-doped layer in which a metal is doped in a low-concentration region when the metal-doped layer is formed. When the SiN film doped with a desired metal is formed, it is required to appropriately control the doping amount of the desired metal.

### RELATED ART DOCUMENT

### [Patent Document]

[Patent Document 1] Japanese Laid-open Patent Application Publication No. 2009-260151

### SUMMARY

According to an aspect of the present disclosure, with respect to a film deposition method of depositing a silicon nitride film doped with a desired metal on a substrate, the film deposition method includes (a) supplying a silicon-containing gas into a processing chamber in which the substrate is accommodated, (b) supplying a metal-containing gas into the processing chamber, the metal-containing gas containing the desired metal, (c) supplying a nitrogen-containing gas into the processing chamber, after performing (a) at least once and performing (b) at least once.

### BRIEF DESCRIPTION OF THE DRAWINGS

FIG. 1 is a cross-sectional explanatory view schematically illustrating an overall configuration of a film deposition apparatus according to an embodiment;

FIG. 2A is a cross-sectional view schematically illustrating a stacked structure of a silicon nitride film;

FIG. 2B is a cross-sectional view schematically illustrating a single-layer structure of the silicon nitride film;

FIG. 3A is a flowchart illustrating a process of manufacturing the silicon nitride film having the stacked structure;

FIG. 3B is a flowchart illustrating a process of manufacturing the silicon nitride film having the single-layer structure;

FIG. 4 is a flowchart illustrating a process of a SiAlN pattern in a metal-doped layer forming step;

FIG. 5A is a flowchart illustrating a process of an AlSiN pattern in the metal-doped layer forming step;

FIG. 5B is a flowchart illustrating a process of a SiAlSiN pattern in the metal-doped layer forming step;

FIG. 6A is a graph comparing the Al doping amounts of an AlN layer, an AlSiN layer, and a SiAlN layer;

FIG. 6B is a graph comparing the Al doping amounts of the SiAlN layer and a SiAlSiN layer;

FIG. 7 is an explanatory view schematically illustrating an effect on a substrate when the SiAlN pattern is performed;

FIG. 8 is an explanatory view schematically illustrating an action on the substrate when the SiAlSiN pattern is performed; and

FIG. 9 is a graph indicating the doping amounts of Al in the depth direction with respect to the SiAlN layer and the SiAlSiN layer.

### DETAILED DESCRIPTION OF EMBODIMENTS

In the following, embodiments of the present disclosure will be described with reference to the drawings. In the drawings, the same components are denoted by the same reference symbols, and duplicated description may be omitted.

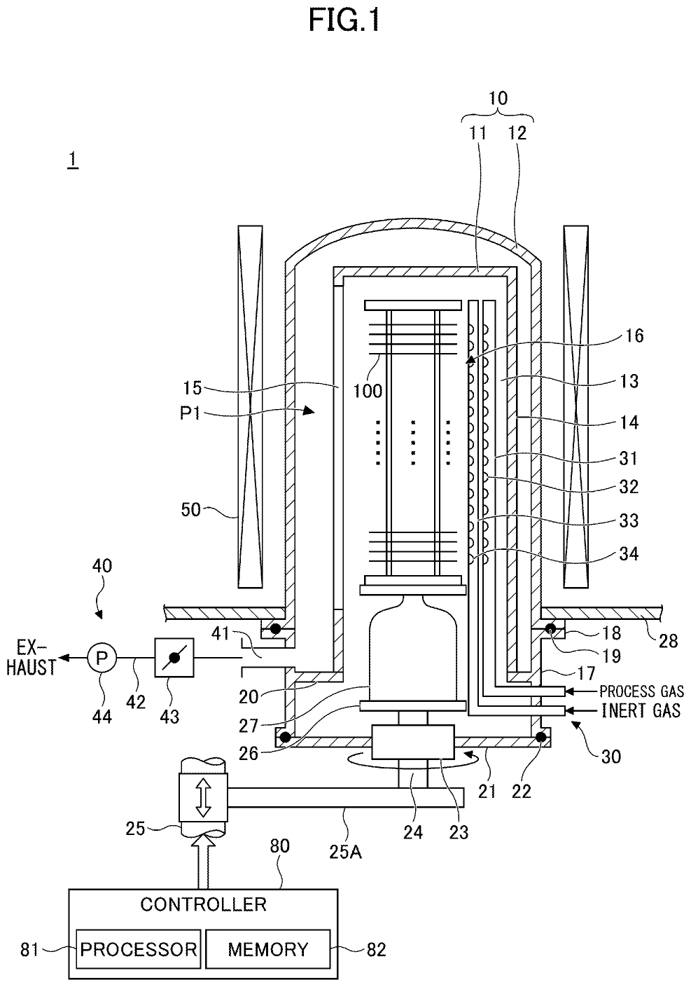

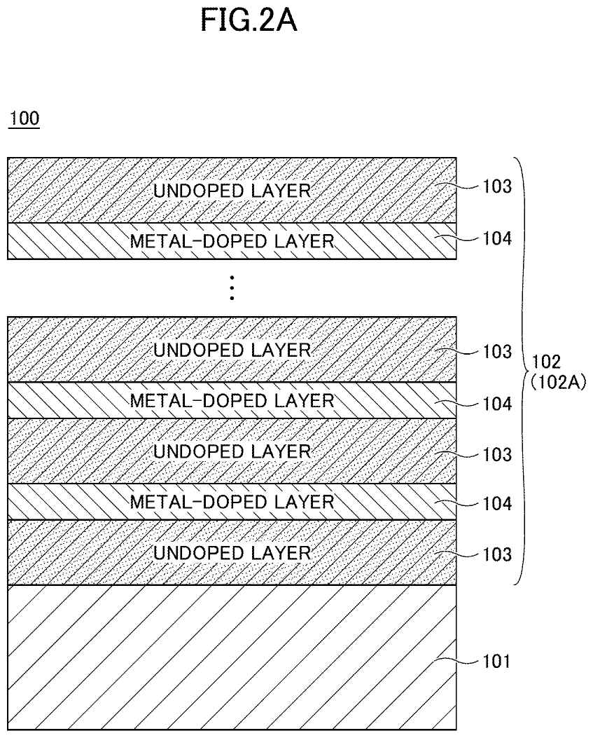

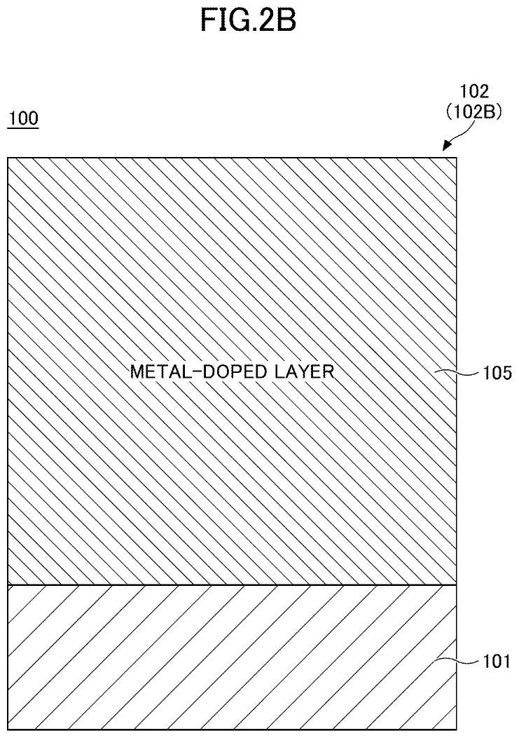

In a film deposition method according to an embodiment of the present disclosure, for example, a silicon nitride film (a SiN film 102; see FIG. 2A and FIG. 2B) doped with a desired metal is deposited on a surface of a substrate 100, using a film deposition apparatus 1 (a substrate processing apparatus) as illustrated in FIG. 1. Hereinafter, in order to facilitate understanding of the present disclosure, first, a configuration of the film deposition apparatus 1 will be described.

The film deposition apparatus 1 includes a processing chamber 10 configured to accommodate multiple substrates 100, a gas supply 30 configured to supply a gas into the processing chamber 10, a gas exhaust section 40 configured to exhaust the gas in the processing chamber 10, a heating element 50 configured to heat the processing chamber 10, and a controller 80 configured to control each component of the apparatus. Additionally, the film deposition apparatus 1 is a thermal atomic layer deposition (ALD) apparatus configured to perform a film deposition process by heating the substrate 100 by the heating element 50 without using plasma.

The processing chamber 10 is formed in a cylindrical shape extending in the vertical direction in order to arrange the multiple substrates 100 in the vertical direction. For example, the processing chamber 10 includes an inner cylinder 11 formed in a cylindrical shape having a flat ceiling and an opening at the lower end, and an outer cylinder 12 formed in a cylindrical shape that covers the outer side of the inner cylinder 11 and that has a dome-shaped ceiling and an opening at the lower end. The inner cylinder 11 and the outer cylinder 12 are formed of a heat-resistant material such as quartz, and have a double structure in which the axial centers of the inner cylinder 11 and the outer cylinder 12 are arranged coaxially. Here, the processing chamber 10 is not limited to the double structure, but may have a single cylinder structure or a multiple structure including three or more cylinders.

At a desired position of the inner cylinder 11 in the circumferential direction, an accommodation portion 13 that accommodates a gas nozzle 31 along the vertical direction is provided. For example, the inner cylinder 11 has a convex portion 14 in which a portion of a side wall of the inner cylinder 11 protrudes outward in the radial direction and extends in the vertical direction, and the accommodation portion 13 is formed inside the convex portion 14.

An opening 15 that is longer in the vertical direction is formed in a side wall of the inner cylinder 11 that is opposite to the accommodation portion 13. The opening 15 exhausts the gas in the inner cylinder 11 to a space P1 between the inner cylinder 11 and the outer cylinder 12. The length of the opening 15 in the vertical direction may be equal to the length of the wafer boat 16 in the vertical direction (or may be longer than the wafer boat 16 in the vertical direction).

A lower end of the processing chamber 10 is supported by a cylindrical manifold 17 formed of stainless steel. A flange 18 protruding outward in the radial direction is formed at the upper end of the manifold 17. The flange 18 supports a flange 12f provided at the lower end of the outer cylinder 12. A seal member 19 that hermetically seals the interior of the outer cylinder 12 and the manifold 17 is provided between the flange 12f and the flange 18.

Additionally, the manifold 17 has an annular support 20, protruding inward in the radial direction, on an inner wall of the upper portion of the manifold 17. The support 20 supports the lower end of the inner cylinder 11. An opening at the lower end of the manifold 17 is air-tightly closed by a cover 21 via a seal member 22. The cover 21 is formed of, for example, stainless steel in a flat plate shape.

A rotation shaft 24, which rotatably supports the wafer boat 16 via a magnetic fluid seal part 23, passes through a central portion of the cover 21. The rotation shaft 24 rotates around an axial center based on a rotational driving force from a driving source and a driving transmission unit (not illustrated) to rotate the wafer boat 16 around a vertical axis.

A lower portion of the rotation shaft 24 is supported by an arm 25A of an elevating mechanism configured by a boat elevator or the like. The film deposition apparatus 1 may vertically move the cover 21 and the wafer boat 16 integrally by vertically moving the arm 25A of the elevating mechanism 25 to insert and retract the wafer boat 16 into and from the processing chamber 10.

A rotation plate 26 is provided at an upper end of the rotation shaft 24, and the wafer boat 16 holding the substrate 100 is mounted on the rotation plate 26 via a heat insulator 27. The wafer boat 16 is a substrate holder that holds the substrates 100 at predetermined intervals in the vertical direction. Each substrate 100 is held by the wafer boat 16 so as to extend along the horizontal direction.

The gas supply 30 is inserted into the processing chamber 10 through the manifold 17. The gas supply 30 introduces a gas such as a process gas, a purge gas, or a cleaning gas into the inner cylinder 11. For example, the gas supply 30 includes a gas nozzle 31 for introducing the process gas and a gas nozzle 33 for introducing the purge gas.

The gas nozzles 31 and 33 are injector pipes made of quartz. The gas nozzles 31 and 33 are provided to pass through the manifold 17 from the inside to the outside of the manifold 17 with extending along the vertical direction of the inner cylinder 11 and being bent in an L-shape at the lower end thereof. The gas nozzle 31 has multiple gas holes 32 at constant intervals along the vertical direction, and discharges the process gas in the horizontal direction through each gas hole 32. Similarly, the gas nozzle 33 has multiple gas holes 34 at constant intervals along the vertical direction, and discharges the purge gas in the horizontal direction through each gas hole 34. The interval between the gas holes 32 and the interval between the gas holes 34 are set to be, for example, the same as the interval between the substrates 100 supported by the wafer boat 16. Additionally, the positions of the gas holes 32 and 34 in the vertical direction are set to be located in the middle between the substrates 100 adjacent to each other in the vertical direction. With this configuration, the gas holes 32 and 34 allow the gas to smoothly flow through the space between the substrates 100.

The gas supply 30 supplies the process gas to the gas nozzle 31 inside the processing chamber 10 while controlling the flow rate of the process gas outside the processing chamber 10. In order to deposit a metal-doped SiN film, the film deposition apparatus 1 according to the present embodiment supplies a silicon-containing gas, a metal-containing gas, and a nitrogen-containing gas as the 173 process gas at different timings.

The silicon-containing gas is a gas for adhering silicon (Si) to the surface of the substrate 100. As the silicon-containing gas, for example, a silane-based compound such as dichlorosilane (DCS: SiH₂Cl₂), monochlorosilane (MCSs: SiClH₃), trichlorosilane (TCS: SiHCl₃), silicon tetrachloride (STC: SiNl₄), or hexachlorodisilane (HCD: Si₂Cl₆) may be suitably used.

The metal-containing gas is a gas containing a desired metal with which the SiN film 102 is to be doped. Examples of the desired metal include aluminum (Al), titanium (Ti), zirconium (Zr), hafnium (Hf), and the like. The metal-containing gas is a material having these desired metals and capable of being distributed as a gas (such as chloride). For example, in the case where the film is to be doped with Al, aluminum chloride (AlCl₃) can be applied as the metal-containing gas. Additionally, in the case where the film is to be doped with Ti, titanium chloride (TiCl₄) may be applied as the metal-containing gas.

The nitrogen-containing gas is appropriately selected according to the silicon-containing gas, the metal-containing gas, and the like. For example, when the silicon-containing gas and the metal-containing gas are chloride-based gases, ammonia (NH 3) gas, hydrazine (N₂H₄) gas, or a derivative thereof such as a monomethyl hydrazine (MMH) gas may be used as the nitrogen-containing gas. Here, the nitrogen-containing gas in the present embodiment does not include a gas containing nitrogen molecules (N₂) alone.

Additionally, the gas supply 30 supplies the purge gas to the gas nozzle 33 inside the processing chamber 10 while controlling the flow rate of the purge gas outside the processing chamber 10. As the purge gas, for example, a gas containing nitrogen molecules (N₂) alone or an inert gas such as argon (Ar) gas may be used.

The gas supply 30 is not limited to the configuration in which the process gas and the purge gas are supplied into the processing chamber 10 by the two gas nozzles 31 and 33 as illustrated in FIG. 1. The gas supply 30 may be configured to separately supply the silicon-containing gas, the metal-containing gas, the nitrogen-containing gas, and the purge gas through three or more (e.g., four) gas nozzles. The gas supply 30 may be configured to supply the silicon-containing gas, the metal-containing gas, the nitrogen-containing gas, and the purge gas through one common gas nozzle.

The gas exhaust section 40 exhausts the gas in the processing chamber 10 to the outside. The gas supplied by the gas supply 30 flows out from the opening 15 of the inner cylinder 11 into the space P1 between the inner cylinder 11 and the outer cylinder 12, and is exhausted via a gas outlet 41. The gas outlet 41 is provided in the side wall of the manifold 17 at the upper portion and above the support 20. An exhaust path 42 of the gas exhaust section 40 is connected to the gas outlet 41, and the exhaust path 42 is provided with a pressure regulating valve 43 and a vacuum pump 44 in this order from upstream to downstream. The gas exhaust section 40 suctions the gas in the processing chamber 10 by the vacuum pump 44 and adjusts the flow rate of the gas to be exhausted by the pressure regulating valve 43 to adjust the pressure (internal pressure) in the processing chamber 10.

Additionally, a temperature sensor (not illustrated) configured to detect an internal temperature of the processing chamber 10 is provided inside the processing chamber 10. A thermocouple, a resistance temperature detector, or the like can be applied as the temperature sensor, and the detected temperature is transmitted to the controller 80.

The heating element 50 is formed in a cylindrical shape covering the periphery of the processing chamber 10 and heats each substrate 100 in the processing chamber 10 under the control of the controller 80. Additionally, the heating element 50 may have a temperature control function of supplying a cooling gas between the processing chamber 10 and the heating element 50 in order to cool each substrate 100 in the processing chamber 10.

A computer including a processor 81, a memory 82, an input/output interface (not illustrated), and the like can be applied as the controller 80. The processor 81 is one or a combination of a central processing unit (CPU), a graphics processing unit (GPU), an application specific integrated circuit (ASIC), a field-programmable gate array (FPGA), a circuit including multiple discrete semiconductors, and the like. The memory 82 is a combination of a volatile memory and a non-volatile memory (for example, a compact disc, a digital versatile disc (DVD), a hard disk, a flash memory, and the like).

The memory 82 stores a program for operating the film deposition apparatus 1 and a recipe such as a process condition of substrate processing. The processor 81 controls each component of the film deposition apparatus 1 by reading and executing the program in the memory 82. Here, the controller 80 may be configured by a host computer or multiple client computers that communicate information via a network.

Next, a structure of the SiN film 102 deposited by the above-described film deposition apparatus 1 will be described with reference to FIG. 2A and FIG. 2B.

The substrate 100 after the film deposition includes a base material 101 disposed in the processing chamber 10 before the film deposition method is performed, and the SiN film 102 stacked on the surface of the base material 101 with the film deposition. As described above, the SiN film 102 is a film of SiN including a desired metal that is deposited on the base material 101, and hereinafter, a case where aluminum (Al) is applied as the desired metal will be described in detail. The SiN film 102 may be formed in a stacked structure 102A in which multiple layers are stacked as illustrated in FIG. 2A, or may be formed in a single-layer structure 102B formed of a single layer as illustrated in FIG. 2B.

Specifically, the stacked structure 102A illustrated in FIG. 2A alternately includes an undoped layer 103 formed without being doped with Al and a metal-doped layer 104 formed adjacent to the undoped layer 103 and with being doped with Al. The thickness of the undoped layer 103 and the thickness of the metal-doped layer 104 are not particularly limited, and are each preferably set in a range of several A to several nm, for example. Here, although the lowermost layer adjacent to the base material 101 and the uppermost layer of the SiN film 102 are the undoped layers 103 in FIG. 2A, the stacked structure 102A is not limited to this, and the lowermost layer may be the metal-doped layer 104 or the uppermost layer may be the metal-doped layer 104.

The undoped layer 103 of the SiN film 102 is a layer of SiN that does not contain Al, and a known formation method of forming a SiN film can be employed. For example, the film deposition apparatus 1 forms the undoped layer 103 by performing a step of supplying a silicon-containing gas such as DCS and a step of supplying a nitrogen-containing gas such as NH₃ by the gas supply 30 after the step of supply of the silicon-containing gas in a state where each substrate 100 is accommodated in the processing chamber 10.

The metal-doped layer 104 of the SiN film 102 is a layer of SiN that contains Al. The method of forming the metal-doped layer 104, which will be described in detail later, includes multiple patterns, and an appropriate pattern can be selected in accordance with the Al doping amount in the entire SiN film 102.

With respect to the above, the single-layer structure 102B illustrated in FIG. 2B is formed by continuously depositing the metal-doped layer 105 doped with Al on the base material 101. For the method of forming the metal-doped layer 105, an appropriate pattern described later can be selected.

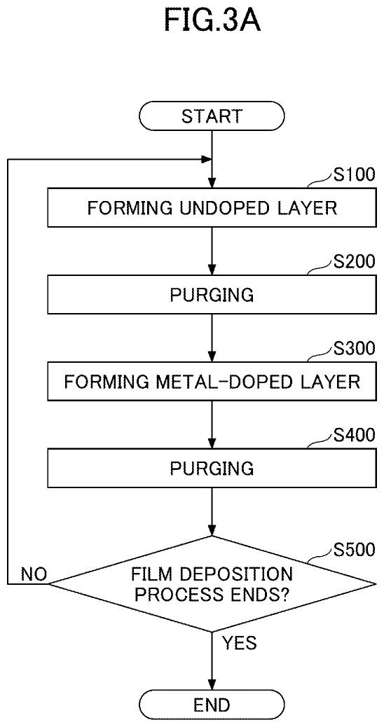

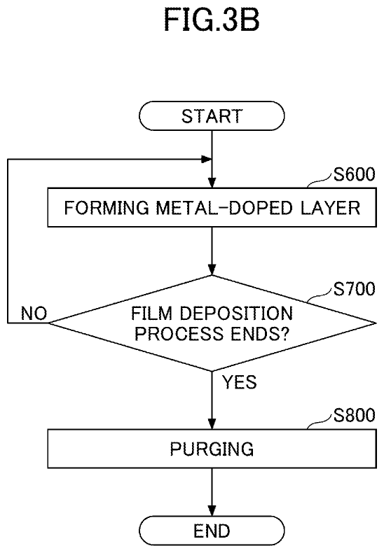

Next, a film deposition method of depositing the SiN film 102 on the base material 101 by the film deposition apparatus 1 will be described with reference to FIG. 3A and FIG. 3B. In the formation of the stacked structure 102A, as illustrated in FIG. 3A, the film deposition apparatus 1 performs a undoped layer forming step (step S100), a purging step (step S200), a metal-doped layer forming step (step S300), and a purging step (step S400) in this order. The undoped layer forming step is a step of depositing the undoped layer 103 that does not contain Al. The metal-doped layer forming step is a step of depositing the metal-doped layer 104 containing Al. The purging step is a step of supplying the purge gas into the processing chamber 10 to exhaust the gas remaining in the processing chamber 10 after each of the undoped layer forming step and the metal-doped layer forming step is performed.

Further, in the film deposition method, it is determined whether to end the film deposition process based on the thickness of the SiN film 102, the number of repetitions of the process, the process time, or the like (step S500). If the film deposition process is to be continued (NO in step S500), the process returns to step S100, and substantially the same steps are repeated. If the film deposition process is to be ended (YES in step S500), the current film deposition method is ended. Here, when the uppermost layer of the stacked structure 102A is the undoped layer 103 as described above, the undoped layer forming step may be performed after the determination of YES in Step S500.

As described, in the film deposition method, each of the thicknesses of the undoped layer 103 and the thickness of the metal-doped layer 104 can be easily controlled by forming the stacked structure 102A. For example, by changing the process time of the undoped layer 103, the relative thickness of the undoped layer 103 with respect to the metal-doped layer 104 can be changed to adjust the Al doping amount in the entire SiN film 102. In other words, in the film deposition method, the Al doping amount in the entirety can be more easily controlled by employing the stacked structure 102A.

In the metal-doped layer forming step (step S300), the film deposition method may adopt the following three manufacturing patterns (a) to (c) according to the order in which the process gases are supplied.
(a) SiAlN pattern: A silicon-containing gas, a metal-containing gas, and a nitrogen-containing gas are supplied in this order to deposit the metal-doped layer 104.
(b) AlSiN pattern: A metal-containing gas, a silicon-containing gas, and a nitrogen-containing gas are supplied in this order to deposit the metal-doped layer 104.
(c) SiAlSiN pattern: A silicon-containing gas, a metal-containing gas, a silicon-containing gas, and a nitrogen-containing gas are supplied in this order to deposit the metal-doped layer 104.

Here, in addition to the manufacturing patterns (a) to (c), the metal-doped layer forming step can adopt various patterns. For example, as another pattern of the metal-doped layer forming step, a pattern in which a metal-containing gas, a silicon-containing gas, a metal-containing gas, and a nitrogen-containing gas are sequentially supplied may be adopted. Alternatively, as the SiAlN pattern, a pattern in which the nitrogen-containing gas is supplied after the supply of the silicon-containing gas and the supply of the metal-containing gas are repeated multiple times may be adopted. Similarly, as the AlSiN pattern, a pattern in which the nitrogen-containing gas is supplied after the supply of the metal-containing gas and the supply of the silicon-containing gas are repeated multiple times may be adopted. Additionally, as the SiAlSiN pattern, a pattern in which the nitrogen-containing gas is supplied after the supply of the silicon-containing gas, the supply of the metal-containing gas, and the supply of the silicon-containing gas are repeated multiple times may be adopted.

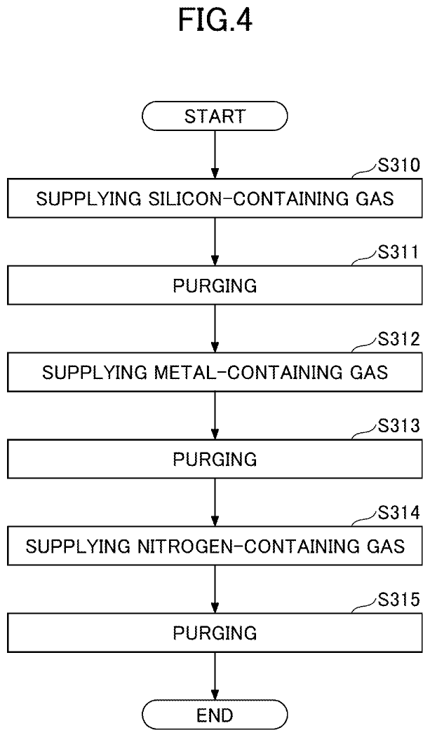

More specifically, (a) SiAlN pattern sequentially performs the steps illustrated in FIG. 4 in the film deposition method. First, the film deposition apparatus 1 performs a silicon-containing gas supplying step of supplying the silicon-containing gas into the processing chamber 10 (step S310). After performing the silicon-containing gas supplying step for a predetermined period of time, the film deposition apparatus 1 stops the supply of the silicon-containing gas and performs a purging step of supplying the purge gas into the processing chamber 10 to exhaust the gas in the processing chamber 10 (step S311).

As process conditions in the silicon-containing gas supplying step (step S310), for example, the following conditions may be set:
the process gas: the silicon-containing gas;
the temperature in the processing chamber 10: 550° C. to 630° C.;
the pressure in the processing chamber 10: 3 Torr to 8 Torr 400 Pa to 1.07 kPa); and
the flow rate of the process gas: 100 sccm to 3000 sccm.

Subsequently, the film deposition apparatus 1 performs a metal-containing gas supplying step of supplying the metal (Al)-containing gas into the processing chamber 10 (step S312). After performing the metal-containing gas supplying step for a predetermined period of time, the film deposition apparatus 1 stops the supply of the metal-containing gas and performs a purging step of supplying the purge gas into the processing chamber 10 to exhaust the gas in the processing chamber 10 (step S313).

As process conditions in the metal-containing gas supplying step (step S312), for example, the following conditions may be set:
the process gas: the metal-containing gas (the Al-containing gas);
the temperature in the processing chamber 10: 400° C. to 640° C.;
the Pressure in the processing chamber 10: 0.1 Torr to 5 Torr 13.3 Pa to 667 Pa); and
the flow rate of the process gas: 100 sccm to 500 sccm.

Further, the film deposition apparatus 1 performs a nitrogen-containing gas supplying step of supplying the nitrogen-containing gas into the processing chamber 10 (step S314). After performing the nitrogen-containing gas supplying step for a predetermined period of time, the film deposition apparatus 1 stops the supply of the nitrogen-containing gas and performs a purging step of supplying the purge gas into the processing chamber to exhaust the gas in the processing chamber 10 (step S315).

As process conditions in the nitrogen-containing gas supplying step (step S314), for example, the following conditions may be set:
the process gas: the nitrogen-containing gas;
the temperature in the processing chamber 10: 550° C. to 630° C.;
the pressures in the processing chamber 10: 8 Torr to 100 Torr 1.07 kPa to 13.3 kPa); and
the flow rate of the process gas: 100 sccm to 13000 sccm.

The film deposition apparatus 1 and the film deposition method can form the metal-doped layer 104 having a target thickness by sequentially performing respective steps of (a) SiAlN pattern described above. Hereinafter, the metal-doped layer 104 formed by (a) SiAlN pattern is also referred to as a SiAlN layer.

Additionally, (b) AlSiN pattern sequentially performs the steps illustrated in FIG. in the film deposition method. In this case, the film deposition apparatus 1 first performs a metal-containing gas supplying step of supplying the metal-containing (Al) gas into the processing chamber 10 (step S321). The process conditions of the metal-containing gas supplying step for the AlSiN pattern may be the same as the process conditions of the metal-containing gas supplying step for the SiAlN pattern described above. After performing the metal-containing gas supplying step for a predetermined period of time, the film deposition apparatus 1 stops the supply of the metal-containing gas and performs a purging step of supplying the purge gas into the processing chamber 10 to exhaust the gas in the processing chamber 10 (Step S322).

Subsequently, the film deposition apparatus 1 performs a silicon-containing gas supplying step of supplying the silicon-containing gas into the processing chamber 10 (step S323). The process conditions of the silicon-containing gas supplying step for the AlSiN pattern may be the same as the process conditions of the silicon-containing gas supplying step for the SiAlN pattern described above. After performing the silicon-containing gas supplying step for a predetermined period of time, the film deposition apparatus 1 stops the supply of the silicon-containing gas and performs a purging step of supplying the purge gas into the processing chamber 10 to exhaust the gas in the processing chamber 10 (step S324).

Further, the film deposition apparatus 1 performs a nitrogen-containing gas supplying step of supplying the nitrogen-containing gas into the processing chamber 10 (step S325). The process conditions of the nitrogen-containing gas supplying step for the AlSiN pattern may be the same as the process conditions of the nitrogen-containing gas supplying step for the SiAlN pattern described above. After performing the nitrogen-containing gas supplying step for a predetermined period of time, the film deposition apparatus 1 stops the supply of the nitrogen-containing gas and performs a purging step of supplying the purge gas into the processing chamber 10 to exhaust the gas in the processing chamber 10 (step S326).

In the film deposition apparatus 1 and the film deposition method, the metal-doped layer 104 having a target thickness can also be formed by sequentially performing respective steps of (b) AlSiN pattern described above. Hereinafter, the metal-doped layer 104 formed by (b) AlSiN pattern is also referred to as an AlSiN layer.

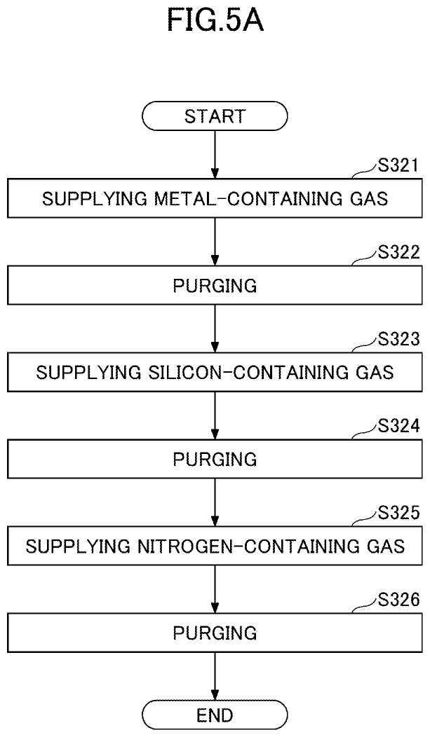

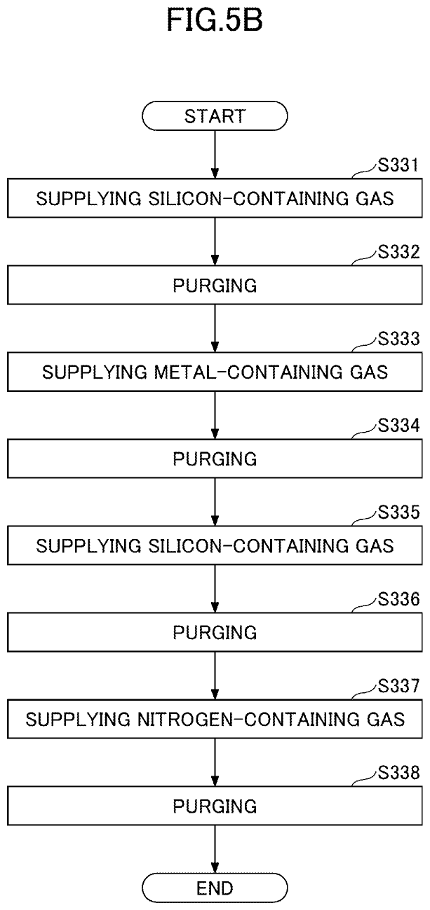

Additionally, (c) SiAlSiN pattern sequentially performs the steps illustrated in FIG. 5B in the film deposition method. In this case, the film deposition apparatus 1 first performs a silicon-containing gas supplying step of supplying the silicon-containing gas into the processing chamber 10 (step S331). The process conditions of the silicon-containing gas supplying step for the SiAlSiN pattern may be the same as the process conditions of the silicon-containing gas supplying step for the SiAlN pattern described above. After performing the silicon-containing gas supplying step for a predetermined period of time, the film deposition apparatus 1 stops the supply of the silicon-containing gas and performs a purging step of supplying the purge gas into the processing chamber 10 to exhaust the gas in the processing chamber 10 (step S332).

Then, the film deposition apparatus 1 performs a metal-containing gas supplying step of supplying the metal (Al)-containing gas into the processing chamber 10 (step S333). The process conditions of the metal-containing gas supplying step for the SiAlSiN pattern may be the same as the process conditions of the metal-containing gas supplying step for the SiAlN pattern described above. After performing the metal-containing gas supplying step for a predetermined period of time, the film deposition apparatus 1 stops the supply of the metal-containing gas and performs a purging step of supplying the purge gas into the processing chamber 10 to exhaust the gas in the processing chamber 10 (step S334).

Subsequently, the film deposition apparatus 1 performs a silicon-containing gas supplying step of supplying the silicon-containing gas into the processing chamber 10 again (step S335). The process conditions of the silicon-containing gas supplying step may be the same as the process conditions of step S331 or may be different from the process conditions of step S331. For example, the process conditions may be set such that the supply amount of the silicon-containing gas is increased and the internal pressure of the processing chamber 10 is increased. After performing the silicon-containing gas supplying step for a predetermined period of time, the film deposition apparatus 1 stops the supply of the silicon-containing gas and performs a purging step of supplying the purge gas into the processing chamber 10 to exhaust the gas in the processing chamber 10 (step S336).

Further, the film deposition apparatus 1 performs a nitrogen-containing gas supplying step of supplying the nitrogen-containing gas into the processing chamber 10 (step S337). The process conditions of the nitrogen-containing gas supplying step for the SiAlSiN pattern may be the same as the process conditions of the nitrogen-containing gas supplying step for the SiAlN pattern described above. After performing the nitrogen-containing gas supplying step for a predetermined period of time, the film deposition apparatus 1 stops the supply of the nitrogen-containing gas and performs a purging step of supplying the purge gas into the processing chamber 10 to exhaust the gas in the processing chamber 10 (step S338).

The film deposition apparatus 1 and the film deposition method can also form the metal-doped layer 104 having a desired thickness by sequentially performing the respective steps of (c) SiAlSiN pattern described above. Hereinafter, the metal-doped layer 104 formed by (c) SiAlSiN pattern is also referred to as a SiAlSiN layer.

The SiAlN layer formed by the SiAlN pattern described above, the AlSiN layer formed by the AlSiN pattern, and the SiAlSiN layer formed by the SiAlSiN pattern have basically the same composition. That is, a deposited film formed of silicon nitride (SiN) is doped with aluminum (Al), which is a metal.

Here, in a conventional film deposition method of forming a SiN film doped with Al, the formation of the undoped layer 103 by the undoped layer forming step and the formation of the metal-doped layer 104 by the metal-doped layer forming step (hereinafter, also referred to as a conventional doped layer forming step or an AlN pattern), in which the metal-containing gas supplying step, the purging step, the nitrogen-containing gas supplying step, and the purging step are sequentially performed, are repeated. That is, in the conventional doped layer forming step, the AlN layer is formed without supplying the silicon-containing gas.

In the conventional film deposition method, the Al doping amount is adjusted by changing the ratio of the number of times of performing the conventional doped layer forming step to the number of times of performing the undoped layer forming step. For example, relative to SiN, the Al doping amount, obtained when the undoped layer forming step and the conventional doped layer forming step are performed at a ratio of 2:1, is smaller than the Al doping amount obtained when the undoped layer forming step and the conventional doped layer forming step are performed at a ratio of 1:1. However, when the ratio is changed in order to reduce the Al doping amount, the thickness of the undoped layer 103 is increased, and portions having Al in the entire SiN film 102 are easily distributed unevenly locally.

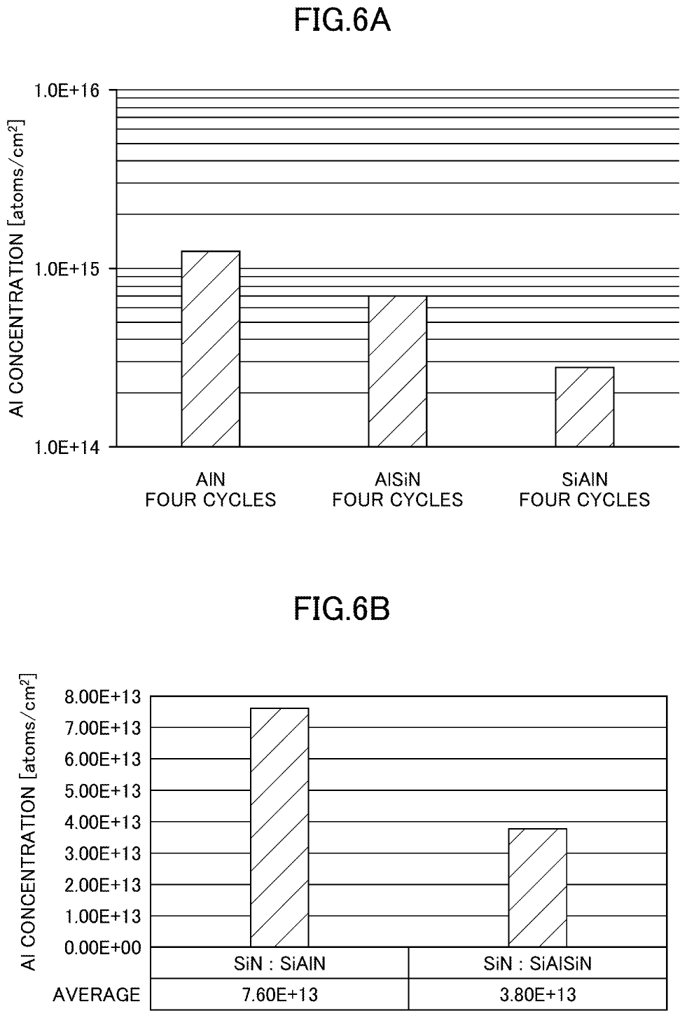

With respect to the above, in the film deposition method according to the present embodiment, the Al doping amount can be appropriately changed relative to SiN by adopting the SiAlN pattern, the AlSiN pattern, and the SiAlSiN pattern in the metal-doped layer forming step. More specifically, as illustrated in FIG. 6A, the Al doping amount in the SiN film 102 decreases in the order of the AlN layer, the AlSiN layer, and the SiAlN layer (AlN layer>AlSiN layer>SiAlN layer). Here, the graph of FIG. 6A is obtained by measuring each Al doping amount when the undoped layer forming step and the metal doped layer forming step are repeated the same number of times (four cycles).

FIG. 6B is a graph illustrating a comparison between the Al doping amount of the SiAlN layer and the Al doping amount of the SiAlSiN layer. Here, also in FIG. 6B, the undoped layer forming step and the metal-doped layer forming step are performed the same number of times to form the SiAlN layer and the SiAlSiN layer are formed such that the thickness of the SiAlN layer is equal to the thickness of the SiAlSiN layer. As can be found from the graph, the SiAlSiN layer has a smaller Al doping amount than the SiAlN layer.

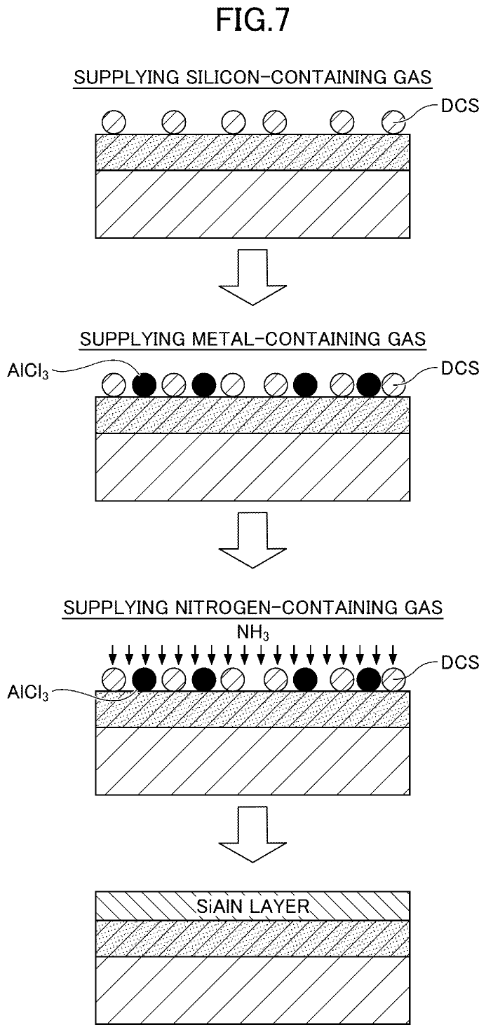

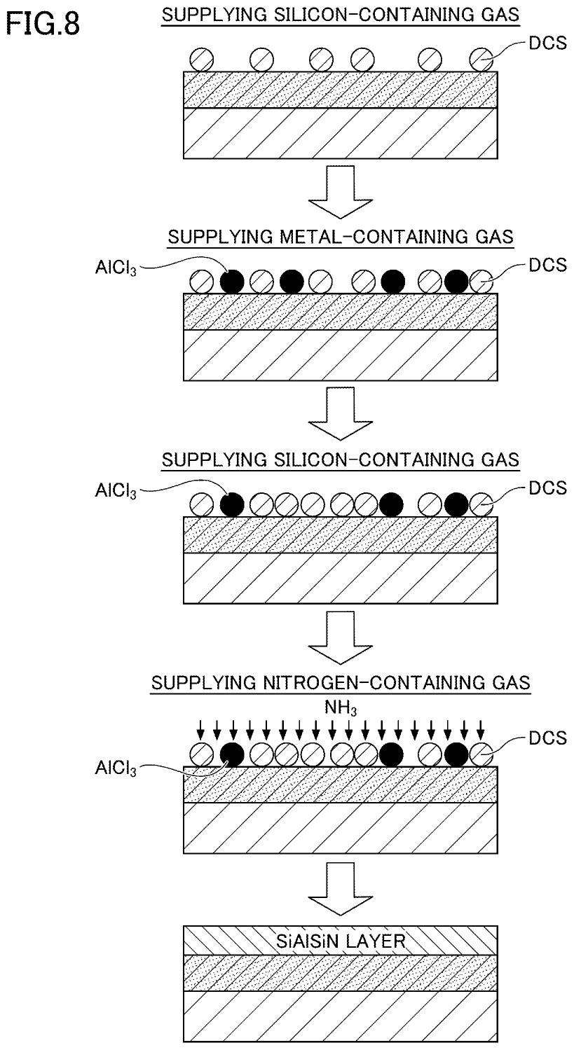

In the following, the principle of variation in the Al doping amount when the SiAlN pattern is performed and when the SiAlSiN pattern is performed will be described in detail with reference to FIGS. 7 and 8.

When the SiAlN pattern is performed in the metal-doped layer forming step, as illustrated in FIG. 7, in the film deposition method, first, by supplying, for example, dichlorosilane (DCS) in the silicon-containing gas supplying step, DCS is adhered onto the undoped layer 103. Next, the SiAlN pattern supplies, for example, aluminum chloride (AlCl₃) in the metal-containing gas supplying step, and causes AlCl₃ to be adhered onto the undoped layer 103 or the DCS previously adhered. At this time, because the DCS has been previously adhered, the adherence of the AlCl₃ can be suppressed in comparison with the method of forming the conventional AlN pattern.

Subsequently, in the nitrogen-containing gas supplying step, the SiAlN pattern supplies, for example, ammonia (NH₃) to remove chlorine by hydrogen, so that the metal-doped layer 104 (SiN doped with Al) is formed on the undoped layer 103. In the metal-doped layer 104 formed in this manner, the Al doping amount can be reduced to be less than the doping amount Al in the metal-doped layer formed by performing the conventional AlN pattern.

With respect to the above, when the SiAlSiN pattern is performed in the metal-doped layer forming step, as illustrated in FIG. 8, the film deposition method forms substantially the same state as that of FIG. 7 in the first silicon-containing gas supplying step and the next metal-containing gas supplying step. That is, DCS is adhered onto the undoped layer 103, and AlCl₃ is adhered onto the undoped layer 103 and the previously adhered DCS.

Next, the SiAlSiN pattern performs the silicon-containing gas supplying step again. This causes a portion of the AlCl₃ previously adhered on the undoped layer 103 to be peeled off, and replaced with DCS. Therefore, the deposits on the undoped layer 103 include a smaller amount of AlCl₃ than that of the SiAlN pattern before the nitrogen-containing gas supplying step.

Subsequently, the SiAlSiN pattern forms the metal-doped layer 104 (SiN doped with Al) on the undoped layer 103 in the nitrogen-containing gas supplying step. The metal-doped layer 104 formed in this manner can be a layer doped with further less amount of Al than the metal-doped layer 104 formed in the SiAlN pattern.

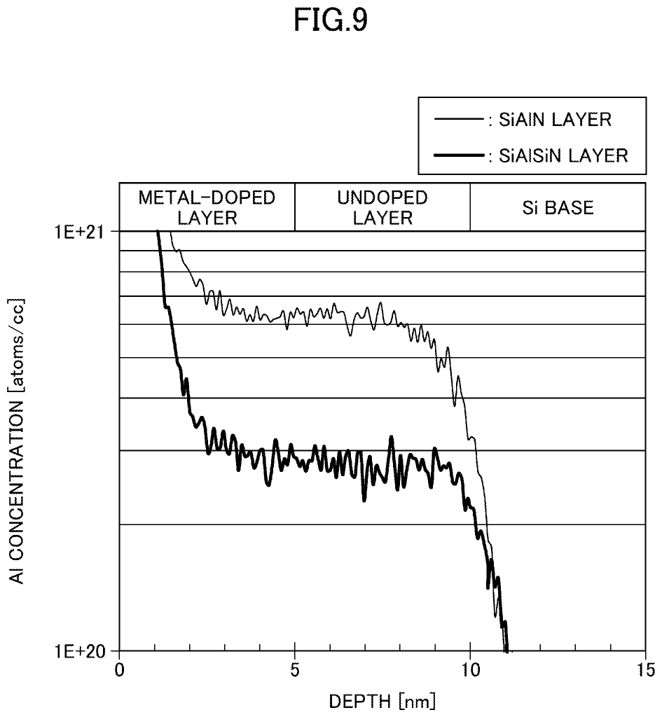

FIG. 9 is a graph obtained by analyzing the Al doping amount of the SiAlN layer formed by the SiAlN pattern in FIG. 7 in the depth direction and the Al doping amount of the SiAlSiN layer formed by the side SiAlSiN pattern of FIG. 8 in the depth direction. Here, in the graph, the Al doping amount of the SiAlN layer is indicated by a solid line, and the Al doping amount of the SiAlSiN layer is indicated by a thick line. As can be found from this graph, in the films of the SiAlN layer and the SiAlSiN layer, the Al doping amount is distributed substantially uniformly in the depth direction.

The Al doping amount of the SiAlSiN layer is less than the Al doping amount in the SiAlN layer overall. This can be regarded as indicating that, as described with reference to FIG. 8, after the metal-containing gas supply process, substitution between Al and Si caused by the second supply of the silicon-containing gas (DCS) reduces the amount of Al. By applying the SiN film 102 doped with Al as described to a semiconductor memory (for example, a 3D NAND memory), the charge retention characteristic of the memory can be improved. In particular, when the Al doping amount is small, the charge retention characteristic of the SiN film 102 is further enhanced.

As described above, the film deposition method can suitably adjust the Al doping amount by supplying the silicon-containing gas and selecting the supply pattern of the process gas in the metal-doped layer forming step. Specifically, when differences in the metal (Al) doping amounts of the metal-doped layers 104 formed in the above-described patterns are summarized, the Al doping amount decreases in the order of the AlN layer, the AlSiN layer, the SiAlN layer, and the SiAlSiN layer (AlN layer>AlSiN layer>SiAlN layer>SiAlSiN layer). Therefore, the film deposition method allows an appropriate amount of Al to be stably doped with the SiN film 102 by selecting the SiAlN pattern, the AlSiN pattern, the SiAlSiN pattern (or an AlN pattern), or the like in accordance with the Al doping amount doped with the entire SiN film 102.

For example, when it is desired to add a low concentration of Al in accordance with the specification of a semiconductor to be manufactured, the film deposition method selects repeating the SiAlN pattern or the SiAlSiN pattern to form the SiAlN layer or the SiAlSiN layer. This can obtain the SiN film 102 having a sufficiently small Al doping amount. Conversely, when it is desired to add a high concentration of Al, the film deposition method repeats the AlSiN pattern (or the AlN pattern) to form the AlSiN layer (or the AlN layer). This allows the SiN film 102 doped with a sufficiently large amount of Al to be obtained.

Here, when forming the single-layer structure 102B illustrated in FIG. 2B, the film deposition method can form the metal-doped layer 105 whose Al doping amount is appropriately adjusted, by applying the SiAlN pattern, the AlSiN pattern, or the SiAlSiN pattern described above. That is, as illustrated in FIG. 3B, the film deposition apparatus 1 immediately performs the metal-doped layer forming step (step S600) in the film deposition method of the single-layer structure 102B. During performing the metal-doped layer forming step, the film deposition apparatus 1 appropriately selects and repeats the SiAlN pattern, the AlSiN pattern, or the SiAlSiN pattern (or the AlN pattern). At this time, the film deposition apparatus 1 may repeat the same pattern among the SiAlN pattern, the AlSiN pattern, and the SiAlSiN pattern (or the AlN pattern), or may switch to a different pattern in order to adjust the Al doping amount.

Additionally, the film deposition apparatus 1 determines whether to end the film deposition process based on the thickness of the SiN film 102, the number of repetitions of the process, the process time, or the like in the film deposition method (step S700). If the film deposition process is to be continued (step S700: NO), the process returns to step S600, and substantially the same steps are repeated. If the film deposition process is to be ended (step S700: YES), the process proceeds to step S800. In step S800, the film deposition apparatus 1 performs the purging step of purging the gas remaining in the processing chamber and ends the current film deposition method.

With the above-described process, even when the single-layer structure 102B is formed, the film deposition apparatus 1 can appropriately adjust the Al doping amount of the entire SiN film 102 by selectively performing the SiAlN pattern, the AlSiN pattern, and the SiAlSiN pattern (or the AlN pattern). Additionally, when the single-layer structure 102B is formed, by not interposing the undoped layer 103 therebetween, the Al doping amount can be reduced and the entire SiN film 102 can be formed such that the thickness of the entire SiN film 102 is thinner.

The technical idea and effects of the present disclosure described in the above embodiments will be described below.

The first aspect of the present disclosure is a film deposition method of depositing a silicon nitride film (the SiN film 102) doped with a desired metal on the substrate 100, and includes (a) a step of supplying a silicon-containing gas into the processing chamber 10 in which the substrate 100 is accommodated (a silicon-containing gas supplying step), (b) a step of supplying a metal-containing gas containing a desired metal into the processing chamber 10 (a metal-containing gas supplying step), and (c) a step of supplying a nitrogen-containing gas into the processing chamber 10, after performing the step (a) at least once and performing the step (b) at least once (a nitrogen-containing gas supplying step).

According to the above, the film deposition method can appropriately control the doping amount of the desired metal in manufacturing the silicon nitride film doped with the desired metal. That is, the film deposition method can appropriately adjust the ratio between the silicon-containing gas and the metal-containing gas on the substrate 100, by performing the silicon-containing gas supplying step and the metal-containing gas supplying step. Therefore, the film deposition method can stably adjust the doping amount of the desired metal with respect to the silicon nitride, by performing the nitrogen-containing gas supplying step after performing the silicon-containing gas supplying step and the metal-containing gas supplying step at least once.

Additionally, the film deposition method performs the step (a) and the step (b) one or more times in this order, and performs the step (c). This allows the film deposition method to suppress the adhesion of the metal-containing gas to the substrate 100, thereby reducing the doping amount of the desired metal.

Additionally, the film deposition method performs the step (b) and the step (a) one or more times in this order, and performs the step (c). This allows the film deposition method to increase the adhesion of the metal-containing gas to the substrate 100, thereby increasing the doping amount of the desired metal.

Additionally, the film deposition method performs the step (a), the step (b), and the step (a) one or more times in this order, and performs the step (c). This allows the film deposition method to replace the metal-containing gas adhering to the substrate 100 with the silicon-containing gas, thereby reducing the doping amount of the desired metal.

Additionally, the film deposition method includes a step of generating the undoped layer 103 formed of silicon nitride that is not doped with the desired metal and a step of generating the metal-doped layer 104 that is doped with the desired metal by performing the steps (a), (b) and (c), and forms the stacked structure 102A of the undoped layer 103 and the metal-doped layer 104 by repeating the step of generating the undoped layer 103 and the step of generating the metal-doped layer 104. This allows the film deposition method to stably reduce the doping amount of the desired metal in the entire stacked structure 102A.

Additionally, in the step of generating the undoped layer, a step of supplying the silicon-containing gas into the processing chamber and a step of supplying the nitrogen-containing gas into the processing chamber are performed one or more times. This allows the film deposition method to easily form the stacked structure 102A of the undoped layer 103 and the metal-doped layer 104 only by changing the supplying pattern of the process gas in the same film deposition apparatus 1.

Additionally, in the manufacturing method, the steps (a), (b), and (c) are repeated multiple times to form the single-layer structure 102B of the metal-doped layer 105 that is doped with the desired metal. This allows the manufacturing method to favorably obtain the single-layer structure 102B in which the doping amount of the desired metal is accurately adjusted.

Additionally, the desired metal is one or a combination of aluminum, titanium, zirconium, and hafnium. This allows the manufacturing method to obtain a silicon nitride film with the charge writing characteristic and charge retention characteristic being enhanced.

Additionally, the second aspect of the present disclosure is the film deposition apparatus 1 that deposits the silicon nitride film doped with the desired metal (the SiN film 102) on the substrate 100, and includes the gas supply 30 configured to supply the process gas into the processing chamber 10 in which the substrate 100 is accommodated, and the controller 80 configured to control an operation of the gas supply 30. The process gas includes a silicon-containing gas, a metal-containing gas containing a desired metal, and a nitrogen-containing gas. The controller 80 performs (a) a step of supplying the silicon-containing gas into the processing chamber 10, (b) a step of supplying the metal-containing gas into the processing chamber 10, and (c) a step of supplying the nitrogen-containing gas into the processing chamber 10 after performing the step (a) at least once and after performing the step (b) at least once. Even in this case, the film deposition apparatus 1 can appropriately control the doping amount of the desired metal in manufacturing the silicon nitride film doped with the desired metal.

The film deposition method and the film deposition apparatus 1 according to the embodiments disclosed herein are illustrative in all respects and are not restrictive. The embodiments can be modified and improved in various forms without departing from the scope and spirit of the appended claims. The matters described in the above embodiments can also take other configurations as long as there is no contradiction, and can be combined as long as there is no contradiction.

According to one aspect, the doping amount of a desired metal can be appropriately controlled at the time of manufacturing a silicon nitride film.

The film deposition apparatus of the present disclosure is not limited to an apparatus that processes multiple substrates, and is also applicable to an apparatus that processes substrates one by one, that is, what is called a single-wafer type apparatus.

What is claimed is:

1. A film deposition method of depositing a silicon nitride film doped with a desired metal on a substrate, the film deposition method comprising:
(a) supplying a silicon-containing gas into a processing chamber in which the substrate is accommodated;
(b) supplying a metal-containing gas into the processing chamber, the metal-containing gas containing the desired metal;
(c) supplying a nitrogen-containing gas into the processing chamber, after performing (a) at least once and performing (b) at least once.

2. The film deposition method as claimed in claim 1, wherein (c) is performed after (a) and (b) are performed in this order one or more times.

3. The film deposition method as claimed in claim 1, wherein (c) is performed after (b) and (a) are performed in this order one or more times.

4. The film deposition method as claimed in claim 1, wherein (c) is performed after (a), (b), and (a) are performed in this order one or more times.

5. The film deposition method as claimed in claim 1, comprising
generating an undoped layer formed of silicon nitride, the undoped layer being not doped with the desired metal;
generating a metal-doped layer by performing (a), (b), and (c), the metal-doped layer being doped with the desired metal, and
wherein a stacked structure of the undoped layer and the metal-doped layer is formed by repeating the generating of the undoped layer and the generating of the metal-doped layer.

6. The film deposition method as claimed in claim 5, wherein the generating of the undoped layer includes supplying a silicon-containing gas into the processing chamber and supplying a nitrogen-containing gas into the processing chamber one or more times.

7. The film deposition method as claimed in claim 1, wherein a single layer structure of a metal-doped layer is formed by repeating (a), (b), and (c) a plurality of times, the metal-doped layer being doped with the desired metal.

8. The film deposition method as claimed in claim 1, wherein the desired metal is one or a combination of aluminum, titanium, zirconium, and hafnium.

9. A film deposition apparatus that deposits a silicon nitride film doped with a desired metal on a substrate, the film deposition apparatus comprising:
a gas supply configured to supply a process gas into a processing chamber in which the substrate is accommodated;
a controller configured to control an operation of the gas supply,
wherein the process gas includes a silicon-containing gas, a metal-containing gas containing the desired metal, and a nitrogen-containing gas; and
wherein the controller performs:
(a) supplying the silicon-containing gas into the processing chamber;
(b) supplying the metal-containing gas into the processing chamber;
(c) supplying the nitrogen-containing gas into the processing chamber, after performing (a) at least once and performing (b) at least once.
